(19) United States
(12) Patent Application Publication
(10) Pub. No.: US 2009/0206460 A1
(43) Pub. Date: Aug. 20, 2009

(54) Intermediate Bond Pad for Stacked Semiconductor Chip Package

(76) Inventors: Elaine Bautista Reyes, Baguio City (PH); Erwin Remoblas Estepa, Baguio City (PH); Edgardo Rulloda Hortaleza, Baguio City (PH)

Correspondence Address: TEXAS INSTRUMENTS INCORPORATED, P O BOX 655474, M/S 3999, DALLAS, TX, 75265, US

(21) Appl. No.: 11/928,996

(22) Filed: Oct. 30, 2007

(51) Int. Cl. H01L 23/49; H01L 21/60

(52) U.S. Cl. 257/686; 438/106; 257/E23.024; 257/E21.509

(57) ABSTRACT

The invention provides apparatus and methods by which, in a stacked semiconductor chip package, a continuous electrical path may be provided among bond pads by way of one or more intermediate bond pad electrically isolated from its underlying surface.

### TECHNICAL FIELD

The invention relates to electronic semiconductor chips and manufacturing. More particularly, the invention relates to microelectronic semiconductor packages having two or more vertically stacked chips contained in a single package and to methods related to their manufacture.

### BACKGROUND OF THE INVENTION

Semiconductor packages are subject to many competing design goals. It is very often desirable to minimize the size of electronic apparatus. At the same time, the demand for increased features results in an increase in the number of components in a given package. Efforts are continuously made to design and manufacture chips with reduced area, but attempts to increase density while reducing area will eventually reach a practical limit. As designers attempt to maximize the use of package area, vertical stacking of semiconductor components within packages becomes increasingly attractive.

Semiconductor packages containing two or more stacked semiconductor chips typically include a first chip that is attached to a package substrate. Bond pads are disposed around some or all of the periphery of the first chip. Bondwires electrically connect the bond pads of the first chip to corresponding bond pads located on the package substrate. A second chip is affixed to the exposed surface of the first chip, sometimes using a spacer between the first and second chips. Bond pads similarly disposed on the top surface of the second chip are then electrically connected to bond pads on the package substrate using bondwires. One or more additional chips may also in turn be stacked in a similar manner to form a multi-layer, multi-chip package containing two, three or more stacked chips operably coupled to the package substrate. Encapsulant is applied to cover the stacked semiconductor chips, wires, bond pads, and at least a portion of the package substrate. Variations in stacking methods and structures exist in terms of materials and process steps, but the overall scheme described above is representative of the general state of the art and provides a context for the description of the invention.

Stacked chip assemblies known in the arts are susceptible to wire-to-wire shorting. For example, in such an assembly, a wire connecting a bond pad on an upper chip to a bond pad on a substrate may pass over one or more wires linking an intervening lower chip to another pad on the substrate. Due to area constraints, the wire for the upper chip-to-substrate connection necessarily passes precariously close to the lower wire. Moreover, during manufacturing the upper wire is more likely to experience excessive displacement, or sweep, due to its higher wire loop profile and greater length. In cases where one or more of the wires becomes displaced and contacts another wire during wirebonding, handling, or molding, a short circuit occurs. The result is the loss of the package, reduced manufacturing yields, and increased costs.

Due to these and other technological challenges, improved semiconductor package assemblies containing stacked chips with improved bondwire connections, and/or methods for manufacturing the same, would be useful and advantageous in the arts. The present invention is directed to overcoming, or at least reducing, one or more of the problems present in the prior art.

### SUMMARY OF THE INVENTION

In carrying out the principles of the present invention, in accordance with preferred embodiments thereof, the invention provides a stacked semiconductor chip package with a continuous electrical path from a substrate bond pad to a bond pad on vertically stacked chip by way of an intermediate bond pad electrically isolated from its surroundings.

According to one aspect of the invention, a preferred method for wirebonding in a stacked semiconductor chip package includes steps of providing a substrate having a first terminal bond pad, and affixing a first chip to the substrate. A second chip stacked on the first chip has a second terminal bond pad for coupling to the first terminal bond pad. In a further step, an intermediate bond pad is provided on the surface of the first chip, from which it is electrically isolated. A wirebond is formed between the intermediate bond pad and the first terminal bond pad, and another wirebond is formed between the intermediate bond pad and the second terminal bond pad. Thus, a continuous electrical path is made to couple the first terminal bond pad with the second terminal bond pad by way of an electrically isolated intermediate bond pad.

According to another aspect of the invention, an example of a preferred embodiment includes the further step of providing an intervening layer between the first chip and the second chip of the stack.

According to another aspect of the invention, another example of a preferred embodiment includes a step of providing an intervening layer between the first chip and the substrate.

According to another aspect of the invention, an example of a preferred embodiment of a stacked semiconductor chip package has a first chip affixed to a substrate and a second chip is affixed to the first chip. The substrate has a first terminal bond pad and the second chip has a second terminal bond pad suitable for coupling to the first terminal bond pad. An intermediate bond pad is provided on the surface of the first chip, and is electrically isolated from the first chip. Wirebonds electrically couple the intermediate bond pad and the first terminal bond pad, and the intermediate bond pad and the second terminal bond pad.

According to yet another aspect of the invention, an embodiment of a stacked semiconductor chip package also includes an intervening layer in the stack, between the first chip and the second chip.

According to still another aspect of the invention, a stacked semiconductor chip package according to a preferred embodiment further includes an intervening layer between the first chip and the substrate.

The invention has advantages including but not limited to one or more of the following: improved wirebonds, improved wirebonding methods, higher manufacturing yields, and decreased costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top perspective view of an example of a preferred embodiment of a stacked chip assembly according to the invention;

FIG. 2 is a cutaway side view of a portion of the stacked chip assembly of FIG. 1; and

FIG. 3 is a top view of an example of a preferred embodiment of a stacked chip assembly according to the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

In a stacked semiconductor chip package, the invention provides a continuous electrical path from a substrate bond pad to a bond pad on vertically stacked chip by way of an intermediate bond pad electrically isolated from its underlying surface.

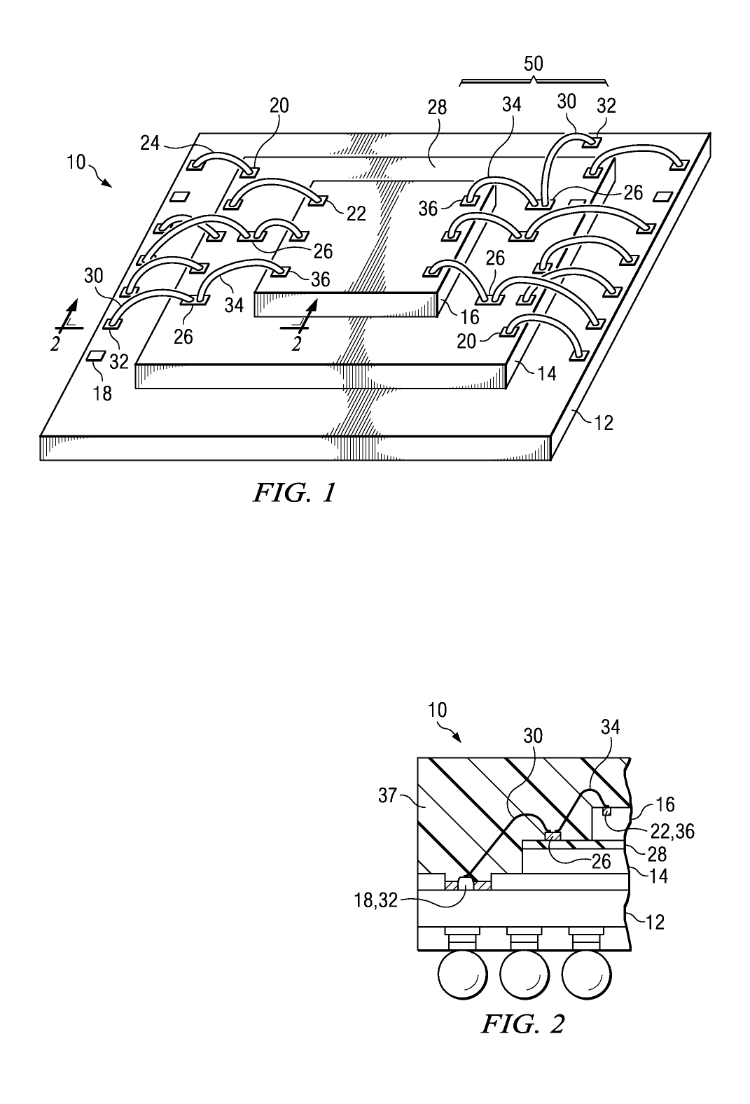

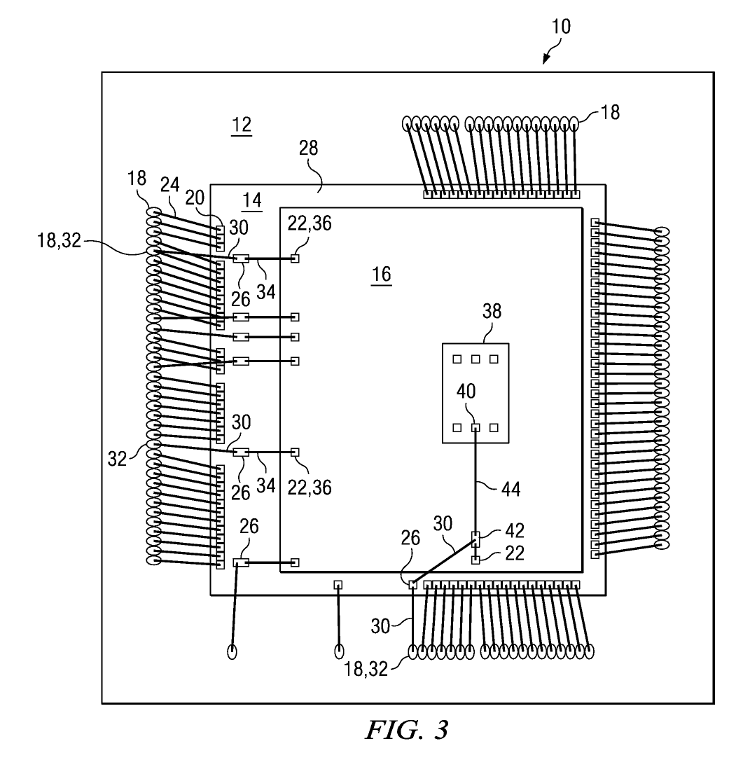

Referring to the drawings, an example of a preferred embodiment of a stacked semiconductor chip package 10 according to the invention is shown in simplified views. The package 10 is based on a substrate 12 such as a multilayer silicon-based substrate as known in the arts. A first chip 14 is affixed to the substrate 12, mechanically bonded in place using suitable adhesives. A second chip 16 is in turn bonded to the surface of the first chip 14 in a similar manner. The substrate 12 includes a number of bond pads 18 as known in the arts for facilitating electrical connections, typically making use of electrical paths (not shown) within the layers of the substrate 12. The first chip 14 also has bond pads 20 generally similar to those (18) on the substrate 12, for making electrical connections from the substrate 12 to the internal electrical paths (not shown) of the first chip 14. Similarly, the second chip 16 includes bond pads 22 as well, for electrically coupling to bond pads 18 of the substrate 12. Bondwires 24 are used to connect the various corresponding bond pads (e.g., 18, 20) of the first chip 14 and substrate 12, as known in the arts. In implementing preferred embodiments of the invention, intermediate bond pads 26 are provided on the surface 28 of the first chip 14 as shown. The intermediate bond pads 26 are electrically isolated from the internal electrical paths (not shown) within the underlying chip 14. Preferably, the intermediate bond pads 26 are formed on the surface of the passive overcoat layer 28 of the underlying chip, in this example, the first chip 14. Alternatively, insulation may be placed under the intermediate bond pad. A bondwire 30 is used to form an electrical path between the intermediate bond pad 26 and a bond pad 18 of the substrate 12. For ease of reference, substrate bond pads (18) connected in this manner are denominated first terminal bond pads 32 herein. A separate bondwire 34 is similarly used to form an electrical path between the intermediate bond pad 26 and a bond pad 22 of the second chip 16. For reference, second chip 16 bond pads (22) connected in this manner are denominated second terminal bond pads 36 herein. As shown, an electrical path is provided from the substrate 12, at a first terminal bond pad 32, to a second terminal bond pad 36, through bondwires, 30, 34, with an intermediate connection at the intermediate bond pad 26. Since the intermediate bond pad 26 is otherwise electrically isolated from its surroundings, for example, by a passive overcoat layer 28 or other insulative coating, a continuous electrical path is provided from the first terminal bond pad 32 to the second terminal bond pad 36. The physical aspects of this path, which includes the isolated intermediate bond pad 26, provides advantages in terms of manufacturing methods and reliability. Those skilled in the arts will recognize that the package 10 is typically encased in encapsulant, represented by reference numeral 37 in FIG. 2, which is omitted from FIGS. 1 and 3 in order to more particularly illustrate aspects of the invention.

In one example of an alternative embodiment of the invention, depicted in the simplified view of FIG. 3, additional chips, in this case a third chip 38, may be included in the stacked package 10. As shown, the third chip 38 has a bond pad 40 on its upper surface, as is typical. A second intermediate bond pad 42 may be provided on the second chip 16, as well as an intermediate bond pad 26 on the first chip 14 in a manner similar to that described. The second intermediate bond pad 42 is electrically isolated from the underlying third chip 38. The second intermediate bond pad 42 is connected by a bondwire 44 to the bond pad 40 of the third chip 38. The second intermediate bond pad 42 is preferably also coupled to a first intermediate bond pad 26 as well, with a separate bondwire 30 as described herein. This is but one example of many potential embodiments of the invention using electrically isolated intermediate bond pads designed and arranged for the purpose of completing electrical connections among distant points within a stacked chip package. The use of the invention advantageously increases flexibility in the design of electrical connections and reduces the potential occurrence of problems such as those associated with wire sweep.

Another alternative variation within the scope of the invention is depicted in FIG. 1. As illustrated at reference numeral 50, an electrical path may use an intermediate bond pad 26 for implementing a change in direction. As shown, in this particular example, a bondwire 30 from a first terminal bond pad 32 is connected to an intermediate bond pad 26 on the first chip 14 and the intermediate bond pad 26 is in turn coupled to a second terminal bond pad 36 on the second chip 16 using a bondwire 34 oriented in a direction different from that of the other bondwire 30. In this example the bondwires 30, 34, are shown in an implementation approximating a ninety degree change in direction for the electrical path 50, illustrating one example of an alternative embodiment in which the invention may be used to advantage in increasing bondwire routing flexibility in providing a noncollinear continuous electrical path among points in a stack.

The methods and systems of the invention provide one or more advantages including but not limited to providing improved wirebonding in stacked semiconductor chip packages. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A method for wirebonding in a stacked semiconductor chip package comprising the steps of:
providing a substrate having a first terminal bond pad;
affixing a first chip to the substrate;
affixing a second chip to the first chip, the second chip having a second terminal bond pad for coupling to the first terminal bond pad;
providing an intermediate bond pad on the surface of the first chip, wherein the intermediate bond pad is electrically isolated from the first chip;
forming a wirebond between the intermediate bond pad and the first terminal bond pad; and
forming a wirebond between the intermediate bond pad and the second terminal bond pad;
thereby forming a continuous electrical path coupling the first terminal bond pad with the second terminal bond pad by way of an electrically isolated intermediate bond pad.

2. The method according to claim 1 further comprising the step of providing an intervening layer between the first chip and the second chip.

3. The method according to claim 1 further comprising the step of providing an intervening layer between the first chip and the substrate.

4. The method according to claim 1 wherein the step of providing an intermediate bond pad on the surface of the first chip further comprises forming the intermediate bond pad on a passive overcoat layer of the first chip.

5. The method according to claim 1 further comprising the step of providing an insulating pad between the intermediate bond pad and the surface of the first chip.

6. The method according to claim 1 whereby the wirebonding steps further comprise forming a noncollinear continuous electrical path coupling the first terminal bond pad with the second terminal bond pad by way of an electrically isolated intermediate bond pad.

7. A stacked semiconductor chip package comprising:
a substrate having a first terminal bond pad;
a first chip affixed to the substrate;
a second chip affixed to the first chip, the second chip having a second terminal bond pad for coupling to the first terminal bond pad;
an intermediate bond pad on the surface of the first chip, wherein the intermediate bond pad is electrically isolated from the first chip;
a wirebond between the intermediate bond pad and the first terminal bond pad; and
a wirebond between the intermediate bond pad and the second terminal bond pad.

8. The stacked semiconductor chip package according to claim 7 further comprising an intervening layer between the first chip and the second chip.

9. The stacked semiconductor chip package according to claim 7 further comprising an intervening layer between the first chip and the substrate.

10. The stacked semiconductor chip package according to claim 7 further comprising an insulating pad interposed between the intermediate bond pad and the surface of the first chip.

11. The stacked semiconductor chip package according to claim 7 further comprising a passive overcoat layer interposed between the intermediate bond pad and the surface of the first chip.

12. The stacked semiconductor chip package according to claim 7 wherein the wirebond between the intermediate bond pad and the first terminal bond pad the wirebond between the intermediate bond pad and the second terminal bond pad form a noncollinear continuous electrical path.

13. A stacked semiconductor chip package comprising:
a semiconductor chip stack having a substrate and a plurality of vertically stacked chips affixed to the substrate;
a first terminal bond pad on the substrate;
a second terminal bond pad on one of the chips of the stack;
an intermediate bond pad on one of the chips of the stack, wherein the intermediate bond pad is electrically isolated from the underlying chip;
a wirebond between the intermediate bond pad and the first terminal bond pad; and
a wirebond between the intermediate bond pad and the second terminal bond pad.

14. The stacked semiconductor chip package according to claim 13 wherein the first terminal bond pad, intermediate bond pad, and second terminal bond pad are each located on a different vertical plane of the stack.

15. The stacked semiconductor chip package according to claim 13 further comprising:
at least one intervening intermediate bond pad, the intervening intermediate bond pad situated on a vertical plane of the stack between the vertical plane of the stack underlying the intermediate bond and the vertical plane of the stack underlying a terminal bond pad;
a bondwire coupling the intermediate bond pad and the intervening intermediate bond pad such that the intermediate bond pad and intervening intermediate bond pad may perform the electrical function of a single isolated intermediate bond pad; wherein
a bondwire couples the first terminal bond pad to the intermediate bond pad and a bondwire couples the second terminal bond pad to the intervening intermediate bond pad, forming a continuous electrical path.

16. The stacked semiconductor chip package according to claim 13 further comprising a passive overcoat layer interposed between the intermediate bond pads and their underlying surfaces.

17. The stacked semiconductor chip package according to claim 13 wherein the continuous electrical path defined by the terminal bond pads and intervening bond pads is noncollinear.
